(19) United States
(12) Patent Application Publication
(10) Pub. No.: US 2025/0292989 A1
(43) Pub. Date: Sep. 18, 2025

(54) CHARGED PARTICLE BEAM DEVICE AND SUBSTRATE DETACHING METHOD

(71) Applicant: Hitachi High-Tech Corporation, Tokyo (JP)

(72) Inventors: Ryo KADOI, Tokyo (JP); Wen Li, Tokyo (JP); Naoya Ishigaki, Tokyo (JP)

(21) Appl. No.: 19/074,889

(22) Filed: Mar. 10, 2025

(30) Foreign Application Priority Data
Mar. 12, 2024 (JP) 2024-037997

(51) Int. Cl. H01J 37/02; H01J 37/147; H01J 37/20; H01J 37/244; H01J 37/28

(52) U.S. Cl. CPC H01J 37/026; H01J 37/1474; H01J 37/20; H01J 37/244; H01J 37/28; H01J 2237/0041; H01J 2237/2007

(57) ABSTRACT

[Problem to be Solved]

Provided is a charged particle beam device and a substrate detaching method that are capable of measuring a charge amount before an influence of a residual adsorption force occurs and reducing the residual adsorption force due to charges.

[Solution]

A charged particle beam device 1 includes: a scanning deflector 13 configured to perform scanning with a charged particle beam 11 emitted from a charged particle source 10 on a surface of a substrate 102; signal electron deflectors (15, 19) configured to deflect a trajectory of a signal electron emitted from the substrate 102 adsorbed to an electrostatic chuck 101; detectors (17, 21) configured to detect the signal electron obtained based on the scanning with the charged particle beam 11; and a controller 100. The electrostatic chuck 101 includes adsorption power supplies (105, 106) and electrodes (103, 104), a voltage dividing capacitor 107 is provided between the electrode and a voltage reference ground 112, the controller 100 includes a peak value detection integration unit 108 configured to integrate a peak value of an intermediate voltage waveform of the voltage dividing capacitor 107, and a peak value integration value-charging voltage conversion unit 109 configured to convert the peak value into a charging voltage value of a surface of the electrostatic chuck based on a peak value integration value obtained by the peak value detection integration unit, and the controller 100 includes a cancellation voltage control unit 110 configured to control a voltage for canceling a residual adsorption force based on the charging voltage value, or a charge removing device control unit 502 configured to control a charge removing device 501 configured to remove a charge by an ultraviolet ray.

### CLAIM OF PRIORITY

The present application claims priority from Japanese Patent application serial No.2024-037997, filed on Mar. 12, 2024, the content of which is hereby incorporated by reference into this application.

### TECHNICAL FIELD

The present invention relates to a charged particle beam device and a substrate detaching method.

### BACKGROUND ART

A device including an electrostatic chuck is disclosed in, for example, PTL 1. PTL 1 discloses that the electrostatic chuck is an electrostatic chuck plate.

PTL 1 discloses that a value of a current flowing when a wafer is detached from the electrostatic chuck plate is detected, residual charges of the electrostatic chuck are calculated, a residual charge amount affects a conveyance state of the wafer, and thus the conveyance state of the wafer can be known by obtaining the residual charge amount.

### CITATION LIST

### Patent Literature

PTL 1: JP2007-165917A

### SUMMARY OF INVENTION

### Technical Problem

In the electrostatic chuck for adsorbing/detaching the wafer, a surface itself of the electrostatic chuck may be charged. When the surface is charged, even if the chuck is turned off to be in a detached state, an adsorption force (residual adsorption force) is generated on the wafer. When the wafer is lifted up from the electrostatic chuck, a force is applied, and the wafer is splashed or damaged. For this reason, it is desirable that the electrostatic chuck is brought into the detached state, a charge amount of the surface of the chuck is measured before the wafer is lifted up, and the residual adsorption force is reduced according to the charge amount.

However, in PTL 1, since the charge amount is measured when the wafer is lifted up, it may not be suitable to measure the charge amount before the wafer is lifted up in order to reduce the residual adsorption force.

In view of the above, the invention provides a charged particle beam device and a substrate detaching method that are capable of measuring a charge amount before an influence of a residual adsorption force is generated and reducing the residual adsorption force due to charges.

### Solution to Problem

In order to achieve the above object, a charged particle beam device according to the invention includes: a scanning deflector configured to perform scanning with a charged particle beam emitted from a charged particle source on a surface of a substrate; a signal electron deflector configured to deflect a trajectory of a signal electron emitted from the substrate adsorbed to an electrostatic chuck; a detector configured to detect the signal electron obtained based on the scanning with the charged particle beam; and a controller. The electrostatic chuck includes an adsorption power supply and an electrode, a voltage dividing capacitor is provided between the electrode and a voltage reference ground, the controller includes a peak value detection integration unit configured to integrate a peak value of an intermediate voltage waveform of the voltage dividing capacitor, and a peak value integration value-charging voltage conversion unit configured to convert the peak value into a charging voltage value of a surface of the electrostatic chuck based on a peak value integration value obtained by the peak value detection integration unit, and the controller includes a cancellation voltage control unit configured to control a voltage for canceling a residual adsorption force based on the charging voltage value, or a charge removing device control unit configured to control a charge removing device configured to remove a charge by an ultraviolet ray.

In a method for detaching a substrate from an electrostatic chuck according to the invention, a charged particle beam device includes a scanning deflector configured to perform scanning with a charged particle beam emitted from a charged particle source on a surface of a substrate, a signal electron deflector configured to deflect a trajectory of a signal electron emitted from the substrate adsorbed to an electrostatic chuck, and a detector configured to detect the signal electron obtained based on the scanning with the charged particle beam, and the electrostatic chuck includes an adsorption power supply and an electrode. The method for detaching a substrate includes: a peak value detection integration unit integrating a peak value of an intermediate voltage waveform of the voltage dividing capacitor between the electrode and a voltage reference ground; a peak value integration value-charging voltage conversion unit converting the peak value into a charging voltage value of the surface of the electrostatic chuck based on a peak value integration value obtained by the peak value detection integration unit; and a cancellation voltage control unit controlling a voltage for canceling a residual adsorption force based on the charging voltage value, or a charge removing device control unit controlling a charge removing device configured to remove a charge by an ultraviolet ray.

### Advantageous Effects of Invention

According to the invention, it is possible to provide a charged particle beam device and a substrate detaching method that are capable of measuring a charge amount before an influence of a residual adsorption force is generated and reducing the residual adsorption force due to charges.

Problems, configurations, and effects other than those described above will be clarified by the following description of embodiments.

### BRIEF DESCRIPTION OF DRAWINGS

FIG. 1 is a diagram showing a schematic configuration of a scanning electron microscope (SEM) according to an embodiment of the invention.

FIG. 2 is a block diagram showing a peripheral configuration of an electrostatic chuck according to Embodiment 1 of the invention.

FIG. 3 is a diagram showing a relationship between a voltage dividing capacitor peak value integration value and a charging voltage of a chuck surface according to Embodiment 1.

FIG. 4 is a flowchart showing operations of detecting charges and canceling a residual adsorption force according to Embodiment 1.

FIG. 5 is a block diagram showing a peripheral configuration of an electrostatic chuck according to Embodiment 2 of the invention.

FIG. 6 is a block diagram showing a peripheral configuration of an electrostatic chuck according to Embodiment 3 of the invention.

### DESCRIPTION OF EMBODIMENTS

In the present description, examples of a charged particle beam device include a scanning electron microscope (SEM) and a focused ion beam (FIB) device, but in the present description, the SEM will be described as an example. A term “substrate” includes a “glass substrate” and the like in addition to a “wafer”.

In the present description, at least secondary electrons (SE), back scattered electrons (BSE), and the like generated from a sample are referred to as signal electrons generated from the sample.

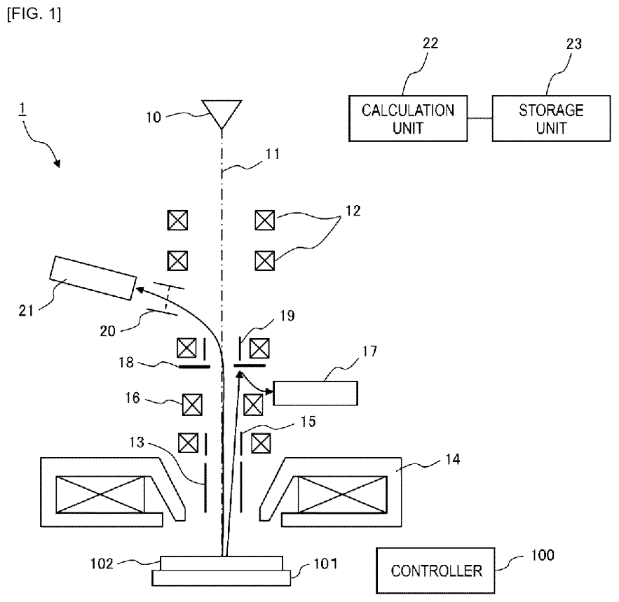

FIG. 1 is a diagram showing a schematic configuration of the scanning electron microscope (SEM) according to an embodiment of the invention. As shown in FIG. 1, the scanning electron microscope 1 includes, as main components, an electron source 10, a condenser lens 12, a primary electron deflector (scanning deflector) 13, an objective lens 14, a signal electron deflector 15, a condenser lens (divergence angle adjustment lens) 16, a detector 17, a signal electron diaphragm 18, a signal electron deflector 19, a detector 21, a calculation unit 22, and a storage unit 23. Although not shown, the scanning electron microscope 100 also includes a display unit that receives an input by the user and displays various parameters and observation patterns. Here, the calculation unit 22 is implemented by, for example, a processor such as a CPU (not shown), a ROM that stores various programs, a RAM that temporarily stores data in a calculation process, and a storage device such as an external storage device, and the processor such as a CPU reads and executes the various programs stored in the ROM, and stores a calculation result, which is an execution result, in the RAM, the external storage device, or a cloud storage via a network connection.

As shown in FIG. 1, in the scanning electron microscope 1, an electron beam (primary electron beam) 11 generated by the electron source 10 is converged by the condenser lens 12 and is converged by the objective lens 14 onto the substrate 102 for irradiation. At this time, a divergence angle of the electron beam (primary electron beam) 11 can be adjusted by the condenser lens (divergence angle adjustment lens) 12. The primary electron deflector (scanning deflector) 13 causes the electron beam (primary electron beam) 11 to scan an electron beam scanning region of the substrate 102 adsorbed to the electrostatic chuck 101. By irradiating and two-dimensionally scanning the substrate 102 with the electron beam (primary electron beam) 11, signal electrons excited in the substrate 102 and emitted from the substrate 102 are detected by the detector 17 and the detector 21, and a detection signal thereof is converted into an image by the calculation unit 22, thereby acquiring an observation image of the substrate 102. Through the signal electron deflector 15, the signal electrons emitted from the substrate 102 are divided into electrons passing through the signal electron diaphragm 18 and electrons colliding with the signal electron diaphragm 18. The electrons colliding with the signal electron diaphragm 18 generate tertiary electrons, and the tertiary electrons are detected by the detector 17. The electrons passing through the signal electron diaphragm 18 are deflected toward the detector 21 through the signal electron deflector 15, and are detected by the detector 21. As shown in FIG. 1, in a part of the scanning electron microscope, an energy filter 20 capable of discriminating the signal electrons by energy is provided in front of the detector 21, and the detector 21 detects electrons passing through the energy filter 20. The calculation unit 22 executes control of each optical element provided in the scanning electron microscope 1, control of a voltage applied to the energy filter 20, control of a deflection amount of the signal electron deflector 19, calculation of a synthesis ratio of signals detected by the detector 21 and the detector 21, and the like. The calculation unit 22 creates the observation image of the substrate 102 using the detection signals of the signal electrons detected by the detector 21 and the detector 21. The scanning electron microscope 1 also includes a controller 100 that controls a charged state of the electrostatic chuck 101.

Hereinafter, embodiments of the invention, in particular, the controller 100 that controls the charged state of the electrostatic chuck 101 will be described with reference to the drawings.

### Embodiment 1

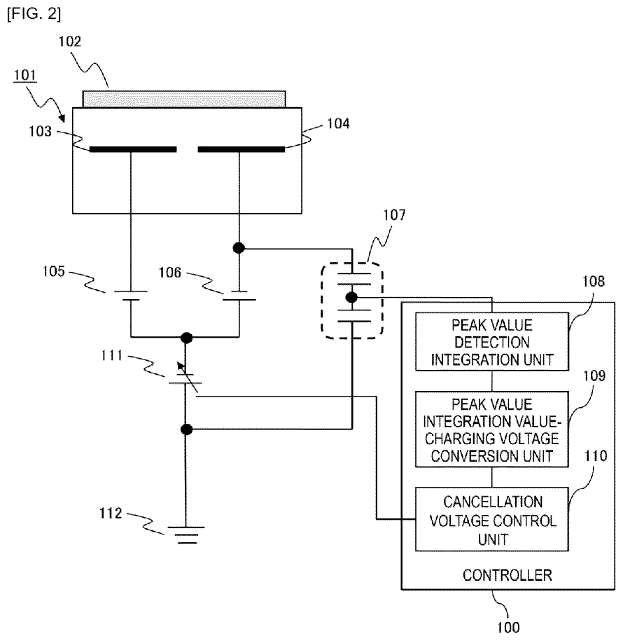

FIG. 2 is a block diagram showing a peripheral configuration of an electrostatic chuck according to Embodiment 1 of the invention. As shown in FIG. 2, the electrostatic chuck 101 that adsorbs the substrate 102, the substrate 102, a positive electrode 103 and a negative electrode 104 for generating a Coulomb force for the adsorption, a positive power supply 105 and a negative power supply 106 for applying a high voltage to the electrodes, a voltage dividing capacitor 107 for dividing charges generated on a surface of the electrostatic chuck 101 using two series capacitors on a negative electrode 104 side and detecting the divided charges, a peak value detection integration unit 108 that detects a peak value of a waveform divided by the voltage dividing capacitor 107 and that integrates the peak value, a peak value integration value-charging voltage conversion unit 109 that converts the peak value into a charging voltage value of the surface of the electrostatic chuck 101 based on the peak value integration value, a cancellation voltage control unit 110 that controls a voltage for canceling a residual adsorption force based on the charging voltage value, a cancellation voltage power supply 111 that generates the voltage for canceling the residual adsorption force, and a voltage reference ground 112 are provided. The peak value detection integration unit 108, the peak value integration value-charging voltage conversion unit 109, and the cancellation voltage control unit 110 constitute the controller 100, and are implemented by, for example, a processor such as a CPU (not shown), a ROM that stores various programs, a RAM that temporarily stores data in a calculation process, and a storage device such as an external storage device. The processor such as a CPU reads and executes the various programs stored in the ROM, and stores a calculation result, which is an execution result, in the RAM, the external storage device, or a cloud storage via a network connection.

Here, a principle of detecting the charges of the surface of the electrostatic chuck 101 by the voltage dividing capacitor 107 will be described. Since the electrostatic chuck 101 itself is an insulator and the negative electrode 104 is a conductor, a circuit element between the surface of the electrostatic chuck 101 and the negative electrode 104 can be considered as a capacitor model. Three series capacitors are formed by the capacitor model and the voltage dividing capacitor 107. Since the capacitor connected in series performs an operation of dividing an AC component and outputting the divided AC component, the voltage dividing capacitor 107 divides and outputs an AC fluctuation component of a voltage when charges are generated on the surface of the electrostatic chuck 101, and an AC voltage peak value at a middle point of the voltage dividing capacitor 107 becomes a voltage proportional to the voltage generated by the charges. Therefore, by measuring an output of the voltage dividing capacitor 107, back calculation can be performed on the charging voltage of the surface of the electrostatic chuck 101. Further, if an AC output peak value of the voltage dividing capacitor 107 is integrated, a voltage change amount due to new charges is integrated each time the charges are generated. Therefore, the voltage change amount becomes a value proportional to a total charging voltage of the surface of the electrostatic chuck 101, and the total charging voltage can be known by the back calculation.

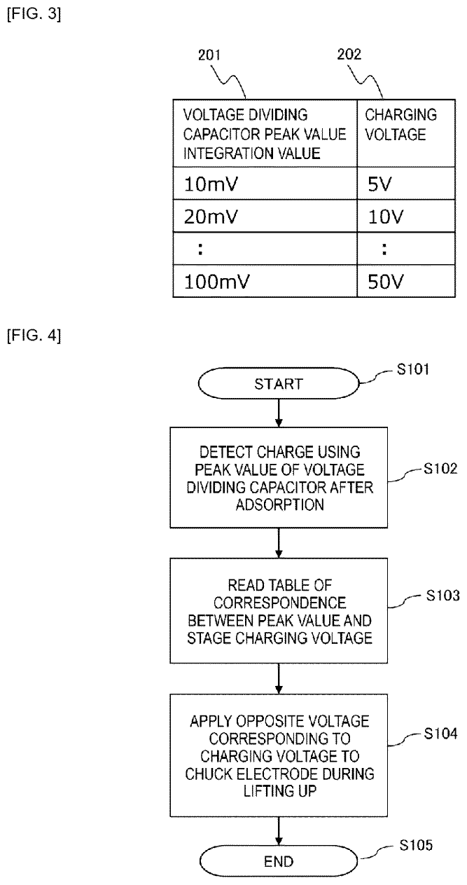

FIG. 3 is a table showing a correspondence between the peak value integration value of the voltage dividing capacitor and the charging voltage of the surface of the electrostatic chuck 101. A relationship between the charging voltage when the surface of the electrostatic chuck 101 is charged and the peak value of the output of the voltage dividing capacitor 107 is measured in advance, and is stored as table data (table) in the storage unit 23 shown in FIG. 1 or a storage unit not shown in FIG. 2. As shown in FIG. 3, when a voltage dividing capacitor peak value integration value 201 is 10 mV, a charging voltage 202 is 5 V. When the voltage dividing capacitor peak value integration value 201 is 20 mV, the charging voltage 202 is 10 V. When the voltage dividing capacitor peak value integration value 201 is 100 mV, the charging voltage 202 is 50 V. Here, for example, when the voltage dividing capacitor peak value integration value 201 is 15 mV, the peak value integration value-charging voltage conversion unit 109 calculates the charging voltage 202 as 7.5 V by linear interpolation. The interpolation method is not limited to the linear interpolation, and other interpolation methods may be adopted.

FIG. 4 is a flowchart showing operations of detecting the charges and canceling the residual adsorption force according to the present embodiment. As shown in FIG. 4, a detection operation is started in step S101, and in step S102, the peak value detection integration unit 108 constituting the controller 100 measures and integrates the peak value when the charges are generated. In step S103, the charging voltage of the surface of the electrostatic chuck 101 is derived from the table shown in FIG. 2 based on a detection voltage integrated by the peak value integration value-charging voltage conversion unit 109 constituting the controller 100 before the substrate 102 is detached from and lifted up from the electrostatic chuck 101. Thereafter, in step S104, the cancellation voltage control unit 110 constituting the controller 100 obtains a voltage having a sign opposite to that of the charging voltage derived in step S103 before lifting up the substrate 102 after the detachment, generates the voltage from the cancellation voltage power supply 111, causes the substrate 102 to be lifted up in a state where the residual adsorption force is cancelled, and ends the process (step S105).

According to the above configuration and process, even when charges are generated on the surface of the electrostatic chuck 101, the charging voltage can be detected before the substrate 102 is lifted up, the cancellation voltage corresponding to the voltage can be applied, and the residual adsorption force due to the charges can be reduced.

In the present embodiment, the voltage dividing capacitor 107, and the peak value detection integration unit 108, the peak value integration value-charging voltage conversion unit 109, and the cancellation voltage control unit 110 that constitute the controller 100 are provided on a negative electrode 104 side of the electrostatic chuck 101, but the invention is not limited thereto. For example, the peak value detection integration unit 108, the peak value integration value-charging voltage conversion unit 109, and the cancellation voltage control unit 110 that constitute the controller 100 may be provided on a positive electrode 103 side. The cancellation voltage power supply 111 is shown as the negative power supply 106. Alternatively, the cancellation voltage power supply 111 may be the positive power supply 105 or both positive and negative output power supplies depending on a charge polarity of the surface of the electrostatic chuck 101. An absolute value of the voltage generated from the cancellation voltage power supply 111 in step S104 is not necessarily exactly the same as the charging voltage, and may be a value obtained by multiplying the charging voltage by a constant proportional coefficient.

As described above, according to the present embodiment, it is possible to provide a charged particle beam device and a substrate detaching method that are capable of measuring a charge amount before an influence of a residual adsorption force is generated and reducing the residual adsorption force due to charges.

### Embodiment 2

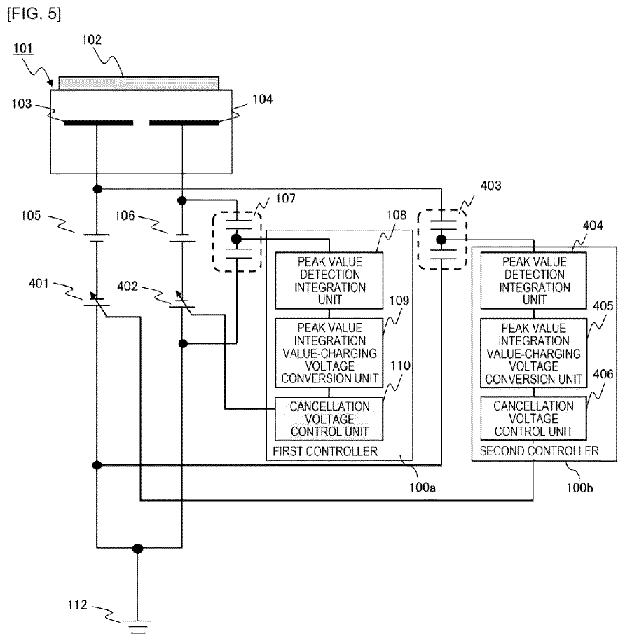

FIG. 5 is a block diagram showing a peripheral configuration of an electrostatic chuck according to Embodiment 2 of the invention. The present embodiment is different from Embodiment 1 in that a second controller 100b including a voltage dividing capacitor 403, a peak value detection integration unit 404, a peak value integration value-charging voltage conversion unit 405, and a cancellation voltage control unit 406 is provided on the positive electrode 103 side in addition to the negative electrode 104 side, and that a cancellation voltage power supply 401 for a positive electrode that applies a cancellation voltage only to the positive electrode 103 and the cancellation voltage power supply 401 for the negative electrode that applies the cancellation voltage only to the negative electrode are provided. In the following, the same components as those in Embodiment 1 are denoted by the same reference signs, and redundant description thereof is omitted.

As shown in FIG. 5, the scanning electron microscope (SEM) 1 according to the present embodiment includes the electrostatic chuck 101 that adsorbs the substrate 102, the substrate 102, the positive electrode 103 and the negative electrode 104 for generating the Coulomb force for the adsorption, the positive power supply 105 and the negative power supply 106 for applying the high voltage to the electrodes, the voltage dividing capacitor 107 for dividing charges generated on the surface of the electrostatic chuck 101 using two series capacitors on the negative electrode 104 side and detecting the divided charges, the peak value detection integration unit 108 that detects the peak value of the waveform divided by the voltage dividing capacitor 107 and that integrates the peak value, the peak value integration value-charging voltage conversion unit 109 that converts the peak value into the charging voltage value of the surface of the electrostatic chuck 101 based on the peak value integration value, the cancellation voltage control unit 110 that controls the voltage for canceling the residual adsorption force based on the charging voltage value, a cancellation voltage power supply 402 that generates the voltage for canceling the residual adsorption force, and the voltage reference ground 112. The peak value detection integration unit 108, the peak value integration value-charging voltage conversion unit 109, and the cancellation voltage control unit 110 constitute a first controller 100a, and are implemented by, for example, a processor such as a CPU (not shown), a ROM that stores various programs, a RAM that temporarily stores data in a calculation process, and a storage device such as an external storage device. The processor such as a CPU reads and executes the various programs stored in the ROM, and stores a calculation result, which is an execution result, in the RAM, the external storage device, or a cloud storage via a network connection.

In addition, the electrostatic chuck 101 that adsorbs the substrate 102, the substrate 102, the positive electrode 103 and the negative electrode 104 for generating the Coulomb force for the adsorption, the positive power supply 105 and the negative power supply 106 for applying the high voltage to the electrodes, a voltage dividing capacitor 403 for dividing charges generated on the surface of the electrostatic chuck 101 using two series capacitors on the positive electrode 103 side and detecting the divided charges, a peak value detection integration unit 404 that detects a peak value of a waveform divided by the voltage dividing capacitor 403 and that integrates the peak value, a peak value integration value-charging voltage conversion unit 405 that converts the peak value into the charging voltage value of the surface of the electrostatic chuck 101 based on the peak value integration value, a cancellation voltage control unit 406 that controls the voltage for canceling the residual adsorption force based on the charging voltage value, the cancellation voltage power supply 401 that generates the voltage for canceling the residual adsorption force, and the voltage reference ground 112 are provided. The peak value detection integration unit 404, the peak value integration value-charging voltage conversion unit 405, and the cancellation voltage control unit 406 constitute the second controller 100b, and are implemented by, for example, a processor such as a CPU (not shown), a ROM that stores various programs, a RAM that temporarily stores data in a calculation process, and a storage device such as an external storage device. The processor such as a CPU reads and executes the various programs stored in the ROM, and stores a calculation result, which is an execution result, in the RAM, the external storage device, or a cloud storage via a network connection.

With such a configuration, even when a charged portion of the surface of the chuck is biased and only the positive electrode 103 side or the negative electrode 104 side is charged, the adsorption force corresponding to the charge amount can be effectively cancelled only for a portion where the residual adsorption force is generated.

As described above, according to the present embodiment, in addition to the effect of Embodiment 1, it is possible to independently control each electrode (the positive electrode 103 and the negative electrode 104). Therefore, it is possible to more effectively cancel the adsorption force according to the charge amount as compared with Embodiment 1.

### Embodiment 3

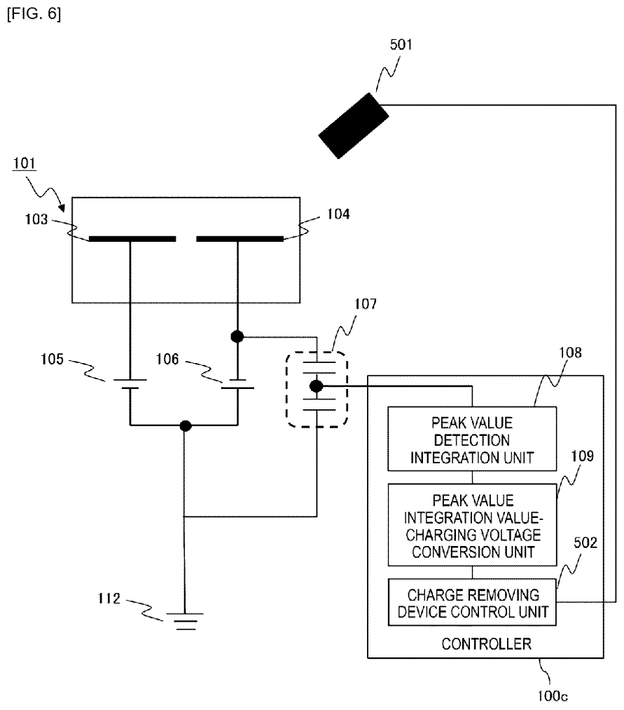

FIG. 6 is a block diagram showing a peripheral configuration of an electrostatic chuck according to Embodiment 3 of the invention. The present embodiment is different from Embodiment 1 in that a charge removing device 501 (for example, an ultraviolet ray source that removes charges by ultraviolet rays) that removes the charges on the surface of the electrostatic chuck 101, and a charge removing device control unit 502 that controls the charge removing device 501 based on a result of the charging voltage detected by the peak value integration value-charging voltage conversion unit are provided. The same elements as those in Embodiment 1 are denoted by the same reference signs, and redundant description thereof is omitted below.

As shown in FIG. 6, the scanning electron microscope (SEM) 1 according to the present embodiment includes the electrostatic chuck 101 that adsorbs the substrate 102, the substrate 102, the positive electrode 103 and the negative electrode 104 for generating the Coulomb force for the adsorption, the positive power supply 105 and the negative power supply 106 for applying the high voltage to the electrodes, the voltage dividing capacitor 107 for dividing charges generated on the surface of the electrostatic chuck 101 using two series capacitors on the negative electrode 104 side and detecting the divided charges, the peak value detection integration unit 108 for detecting the peak value of the waveform divided by the voltage dividing capacitor 107 and integrating the peak value, the peak value integration value-charging voltage conversion unit 109 that converts the peak value into the charging voltage value of the surface of the electrostatic chuck 101 based on the peak value integration value, the charge removing device control unit 502 that controls the charge removing device 501 so as to remove the charges of the surface of the electrostatic chuck 101 after lifting up the substrate 102 when the residual adsorption force exceeds a predetermined threshold at which the residual adsorption force is not a problem, and the voltage reference ground 112. The peak value detection integration unit 108, the peak value integration value-charging voltage conversion unit 109, and the charge removing device control unit 502 constitute a controller 100c, and are implemented by, for example, a processor such as a CPU (not shown), a ROM that stores various programs, a RAM that temporarily stores data in a calculation process, and a storage device such as an external storage device. The processor such as a CPU reads and executes the various programs stored in the ROM, and stores a calculation result, which is an execution result, in the RAM, the external storage device, or a cloud storage via a network connection.

Here, the threshold at which the residual adsorption force is not a problem is set to, for example, the peak voltage dividing capacitor peak value integration value of 20 mV.

By performing such control, it is possible to remove the charges before the residual adsorption force at a level that damages the substrate 102 when the substrate 102 is lifted up is generated.

As described above, according to the present embodiment, the same effects as those of Embodiment 1 can be achieved.

The invention is not limited to the embodiments described above, and includes various modifications. For example, the embodiments described above have been described in detail to facilitate understanding of the invention, and the invention is not necessarily limited to those including all the configurations described above. A part of a configuration of a certain embodiment can be replaced with a configuration of another embodiment, and the configuration of a certain embodiment can be added to the configuration of another embodiment.

### REFERENCE SIGNS LIST

1: scanning electron microscope (SEM)
10: electron source
11: electron beam
12: condenser lens
13: primary electron deflector
14: objective lens
15: signal electron deflector
16: condenser lens (divergence angle adjustment lens)
17: detector
18: signal electron diaphragm
19: signal electron deflector
20: energy filter
21: detector
22: calculation unit
23: storage unit
100, 100c: controller
100a: first controller
100b: second controller
101: electrostatic chuck
102: substrate
103: positive electrode
104: negative electrode
105: positive power supply
106: negative power supply
107, 403: voltage dividing capacitor
108, 404: peak value detection integration unit
109, 405: peak value integration value-charging voltage conversion unit
110, 406: cancellation voltage control unit
111, 401, 402: cancellation voltage power supply
112: voltage reference ground
201: voltage dividing capacitor peak value integration value
202: charging voltage
501: charge removing device
502: charge removing device control unit

1. A charged particle beam device comprising:
a scanning deflector configured to perform scanning with a charged particle beam emitted from a charged particle source on a surface of a substrate;
a signal electron deflector configured to deflect a trajectory of a signal electron emitted from the substrate adsorbed to an electrostatic chuck;
a detector configured to detect the signal electron obtained based on the scanning with the charged particle beam; and
a controller, wherein
the electrostatic chuck includes an adsorption power supply and an electrode,
a voltage dividing capacitor is provided between the electrode and a voltage reference ground,
the controller includes a peak value detection integration unit configured to integrate a peak value of an intermediate voltage waveform of the voltage dividing capacitor, and a peak value integration value-charging voltage conversion unit configured to convert the peak value into a charging voltage value of a surface of the electrostatic chuck based on a peak value integration value obtained by the peak value detection integration unit, and
the controller includes a cancellation voltage control unit configured to control a voltage for canceling a residual adsorption force based on the charging voltage value, or a charge removing device control unit configured to control a charge removing device configured to remove a charge by an ultraviolet ray.

2. The charged particle beam device according to claim 1, further comprising:
a cancellation voltage power supply, wherein
the cancellation voltage control unit obtains a voltage having a sign opposite to that of the charging voltage value before the substrate is lifted up, and applies the obtained opposite voltage to the electrode from the cancellation voltage power supply.

3. The charged particle beam device according to claim 2, wherein
the peak value integration value-charging voltage conversion unit reads a table indicating a correspondence between the peak value integration value stored in advance and a charging voltage of the surface of the electrostatic chuck, and sets the read value as the charging voltage value.

4. The charged particle beam device according to claim 2, further comprising:
a first voltage dividing capacitor, and a first controller including the peak value detection integration unit, the peak value integration value-charging voltage conversion unit, and the cancellation voltage control unit on a negative electrode side of the electrostatic chuck; and
a second voltage dividing capacitor, and a second controller including the peak value detection integration unit, the peak value integration value-charging voltage conversion unit, and the cancellation voltage control unit on a positive electrode side of the electrostatic chuck, wherein
based on the charging voltage value of each electrode, a first cancellation voltage power supply connected to a negative electrode or a second cancellation voltage power supply connected to a positive electrode applies the opposite voltage to the electrode.

5. The charged particle beam device according to claim 1, further comprising:
the charge removing device, wherein
when the charging voltage value exceeds a predetermined threshold, the charge removing device control unit controls the charge removing device to remove the charge from the surface of the electrostatic chuck after the substrate is lifted up.

6. A method for detaching a substrate from an electrostatic chuck, a charged particle beam device including a scanning deflector configured to perform scanning with a charged particle beam emitted from a charged particle source on a surface of a substrate, a signal electron deflector configured to deflect a trajectory of a signal electron emitted from the substrate adsorbed to an electrostatic chuck, and a detector configured to detect the signal electron obtained based on the scanning with the charged particle beam, the electrostatic chuck including an adsorption power supply and an electrode, the method comprising:
a peak value detection integration unit integrating a peak value of an intermediate voltage waveform of the voltage dividing capacitor between the electrode and a voltage reference ground;
a peak value integration value-charging voltage conversion unit converting the peak value into a charging voltage value of a surface of the electrostatic chuck based on a peak value integration value obtained by the peak value detection integration unit; and
a cancellation voltage control unit controlling a voltage for canceling a residual adsorption force based on the charging voltage value, or a charge removing device control unit controlling a charge removing device configured to remove a charge by an ultraviolet ray.

7. The method for detaching a substrate according to claim 6, wherein
the cancellation voltage control unit obtains a voltage having a sign opposite to that of the charging voltage value before the substrate is lifted up, and applies the obtained opposite voltage to the electrode from a cancellation voltage power supply.

8. The method for detaching a substrate according to claim 7, wherein
the peak value integration value-charging voltage conversion unit reads a table indicating a correspondence between the peak value integration value stored in advance and a charging voltage of the surface of the electrostatic chuck, and sets the read value as the charging voltage value.

9. The method for detaching a substrate according to claim 7, wherein
a first voltage dividing capacitor, and a first controller including the peak value detection integration unit, the peak value integration value-charging voltage conversion unit, and the cancellation voltage control unit are provided on a negative electrode side of the electrostatic chuck,
a second voltage dividing capacitor, and a second controller including the peak value detection integration unit, the peak value integration value-charging voltage conversion unit, and the cancellation voltage control unit are provided on a positive electrode side of the electrostatic chuck, and
based on the charging voltage value of each electrode, a first cancellation voltage power supply connected to a negative electrode or a second cancellation voltage power supply connected to a positive electrode applies the opposite voltage to the electrode.

10. The method for detaching a substrate according to claim 6, wherein
the charge removing device is provided, and
when the charging voltage value exceeds a predetermined threshold, the charge removing device control unit controls the charge removing device to remove the charge from the surface of the electrostatic chuck after the substrate is lifted up.
